(19) United States
(12) Patent Application Publication
(10) Pub. No.: US 2020/0043888 A1
(43) Pub. Date: Feb. 6, 2020

(54) SEMICONDUCTOR DEVICE, POWER CONVERSION APPARATUS, AND METHOD FOR MANUFACTURING SEMICONDUCTOR DEVICE

(71) Applicant: Mitsubishi Electric Corporation, Chiyoda-ku, Tokyo (JP)

(72) Inventor: Hiroaki TATSUMI, Tokyo (JP)

(73) Assignee: Mitsubishi Electric Corporation, Chiyoda-ku, Tokyo (JP)

(21) Appl. No.: 16/490,723

(22) PCT Filed: Apr. 26, 2018
(86) PCT No.: PCT/JP2018/017062

§ 371 Date: Sep. 3, 2019

(30) Foreign Application Priority Data
Apr. 27, 2017 (JP) 2017-088268

(51) Int. Cl. H01L 23/00; H02M 7/5387

(52) U.S. Cl. CPC H01L 24/83; H02P 27/08; H01L 24/32; H02M 7/53871; H01L 2224/2929; H01L 2224/29311; H01L 2224/29347; H01L 2224/29409; H01L 2224/29439; H01L 2224/29455; H01L 2224/29499; H01L 2224/29411; H01L 2224/32503; H01L 2224/83194; H01L 2224/83047; H01L 2224/83104; H01L 2224/29011; H01L 2224/83951; H01L 2224/83203; H01L 2224/83862; H01L 2224/8381; H01L 2224/83905; H01L 24/29

(57) ABSTRACT

A bonding material that contains first particles containing a first metal, second particles containing a second metal having a melting point lower than that of the first metal, and filling resin is supplied on one of a semiconductor element or a conductor member, and a gap is formed in a surface of the supplied bonding material. The other of the conductor member or the semiconductor element is mounted on and pressed against the bonding material in which the gap is formed, and the filling resin unevenly distributed on the surface of the bonding material is moved to the gap.

### TECHNICAL FIELD

The present invention relates to a semiconductor device in which a semiconductor element and a conductor member are connected with electrical conduction.

### BACKGROUND ART

A vertical semiconductor element such as an IGBT, a diode, and a MOSFET is mounted on a power conversion semiconductor device used for inverter control of a motor or the like. Electrodes are formed on the front and back surfaces of the semiconductor element by metal metallization, and in the case of a general semiconductor device, the back surface electrode of the semiconductor element and a circuit board are often connected via a solder bonding portion.

Since a heat generation amount of the semiconductor element tends to increase, high heat resistance performance is desired for a bonding material used for such a power module. That is, a bonding portion having a high melting point is required. However, a lead-free solder material having high heat resistance has not been found at present. In addition, as alternative means, development of a sinter bonding technique for achieving bonding by sintering ultrafine particles such as silver is in progress; however, since it is necessary to apply pressure to press a semiconductor element against a substrate in a bonding process, there is a big problem in productivity because of problems such as damage to and contamination of the element in the present situation.

Under such circumstances, in lieu of the above-described solder bonding technique and sinter bonding technique, liquid phase diffusion bonding (Transient Liquid Phase Bonding: TLP bonding) has been examined. In this bonding technique, a bonding material configured of low-melting-point metal particles that melts at bonding temperature and high-melting-point metal particles that do not melt at the bonding temperature is used. When the above-described bonding material is heated at the bonding temperature, the low-melting-point metal particles melt, wetly spread on and are brought into contact with the surfaces of the high-melting-point metal particles, and thus both of them react with each other. As a result, an intermetallic compound having a melting point higher than the bonding temperature is formed, and a bonding portion having a structure in which the high-melting-point metal particles are bonded to each other by the intermetallic compound is obtained. As a result, it is possible to obtain the bonding portion having a high melting point that does not remelt even when exposed to the bonding temperature again.

In Patent Document 1, a material in which Sn particles and Cu particles are used as low-melting-point metal particles and high-melting-point metal particles, respectively, is described. By performing heating at bonding temperature, the Sn particles melt, wetly spread on and contact with the surfaces of the Cu particles to react with each other, and a structure in which the Cu particles are bonded to each other by an intermetallic compound containing Cu₆Sn₅ is formed. As a result, a highly heat-resistant bonding portion made of Cu particles having a high melting point and an intermetallic compound containing Cu₆Sn₅ having a high melting point is obtained. However, in the process of forming a state where the Cu particles are bonded to each other by the intermetallic compound containing Cu₆Sn₅, it is extremely difficult to cause the molten Sn to uniformly flow in a bonding layer and to completely fill the interval between the Cu particles. In other words, in the process of forming a state where the Cu particles are bonded to each other by the intermetallic compound containing Cu₆Sn₅, it is inevitable that a space (void) remains in the bonding layer. There is a risk that this void becomes a starting point and a crack may be caused by stress that occurs upon operation of the product.

In contrast, in Patent Document 2, a bonding material that includes alloy particles containing Cu and Sn and organic binder resin is described. A bonding portion formed by using the bonding material is considered to have a structure in which the alloy particles are bonded to each other and a void between the alloy particles is filled with the organic binder resin.

### PRIOR ART DOCUMENTS

### Patent Documents

Patent Document 1: Japanese Patent No. 3558063

Patent Document 2: WO 2002-028574

### SUMMARY

### Problem to be Solved by the Invention

It is considered that by adding organic binder resin to a bonding material containing high-melting-point metal particles and low-melting-point metal particles as in Patent Document 2 and filling voids between the metal particles, it is possible to reduce cracks starting from the voids. However, since the specific gravity of the metal particle and the specific gravity of the organic binder resin are greatly different, for example, in the case of printing a bonding material on a conductor member and mounting and bonding a semiconductor element on the printed bonding material, the metal particles and the organic binder resin may be unevenly distributed within the bonding material due to the difference in specific gravity. There is a risk that with such a non-uniform bonding portion, conduction between the semiconductor element and the conductor member cannot be ensured, bonding strength also lowers, and bonding failure occurs.

An object of the present invention is to provide a semiconductor device including a bonding portion suppressing uneven distribution in the bonding direction of metal particles, an intermetallic compound and filling resin and having high bonding reliability, and a method for manufacturing the semiconductor device.

### Means to Solve the Problem

A semiconductor device according to the present invention includes: a semiconductor element; a conductor member; and a bonding portion that bonds the semiconductor element and the conductor member with electrical conduction, the bonding portion containing first particles that contain a first metal, an intermetallic compound that contains the first metal and a second metal having a melting point lower than a melting point of the first metal and couples the first particles to each other, and filling resin, the bonding portion having, in a cross section parallel to a bonding direction, mixed metal regions in which a coupled structure including the first particles and the intermetallic compound is continuously formed from a bonding surface with the semiconductor element to a bonding surface with the conductor member, and a mixed resin region which is formed between two of the mixed metal regions that are adjacent to each other, in which a ratio of the filling resin is greater than a ratio of the filling resin in the mixed metal region, and the coupled structure is not in contact with at least one of the semiconductor element or the conductor member.

In addition, a method for manufacturing a semiconductor device according to the present invention includes: a bonding material supply process of supplying a bonding material that contains first particles containing a first metal, second particles containing a second metal having a melting point lower than a melting point of the first metal, and a filling resin on one of a semiconductor element or a conductor member, and forming a gap in a surface of the supplied bonding material; a mounting process of mounting and pressing the other of the conductor member or the semiconductor element on and against the bonding material in which the gap is formed, and moving the filling resin unevenly distributed in the surface of the bonding material to the gap; and a bonding process of heating the bonding material at temperature higher than the melting point of the second metal and lower than the melting point of the first metal.

### Effects of the Invention

According to the present invention, by moving the filling resin unevenly distributed in the surface of the bonding material to the gap provided in the bonding material, uneven distribution of the filling resin in the bonding direction is suppressed, and it is possible to reliably bond the semiconductor element and the conductor member by using the coupled structure including the metal particles and the intermetallic compound, making it possible to obtain a semiconductor device having high bonding reliability.

### BRIEF DESCRIPTION OF DRAWINGS

FIG. 1 shows a perspective view of a main part illustrating a bonding portion of a conductor member and a semiconductor element in a semiconductor device according to a first embodiment of the present invention.

FIG. 2 shows a drawing in which the semiconductor element is not illustrated in FIG. 1.

FIGS. 3A and 3B show schematic views illustrating a bonding material before heated and after heated, used for the bonding portion of the conductor member and the semiconductor element in the semiconductor device of the first embodiment of the present invention.

FIGS. 4A to 4C show perspective views of a main part illustrating a bonding process of the conductor member and the semiconductor element in the semiconductor device according to the first embodiment of the present invention.

FIGS. 5A to 5D show cross-sectional views of a main part illustrating changes in a manufacturing process of the bonding portion of the conductor member and the semiconductor element in the semiconductor device according to the first embodiment of the present invention.

FIGS. 6A and 6B show a cross-sectional view and an enlarged view of a main part thereof illustrating the bonding portion of the conductor member and the semiconductor element in the semiconductor device according to the first embodiment of the present invention.

FIG. 7 shows a cross-sectional view of a main part illustrating a bonding portion of a conductor member and a semiconductor element in a semiconductor device according to a comparative example.

FIGS. 8A to 8D show cross-sectional views of a main part illustrating changes in a manufacturing process of a bonding portion of a conductor member and a semiconductor element in a semiconductor device according to a second embodiment of the present invention.

FIGS. 9A to 9C show cross-sectional views illustrating a method for manufacturing a semiconductor device according to a third embodiment of the present invention.

FIG. 10 shows a schematic view illustrating a power conversion apparatus according to a fourth embodiment of the present invention.

### DESCRIPTION OF EMBODIMENTS

### First Embodiment

Hereinafter, a first embodiment of the present invention will be described based on the drawings. Note that in the drawings, identical reference numerals indicate identical or corresponding parts.

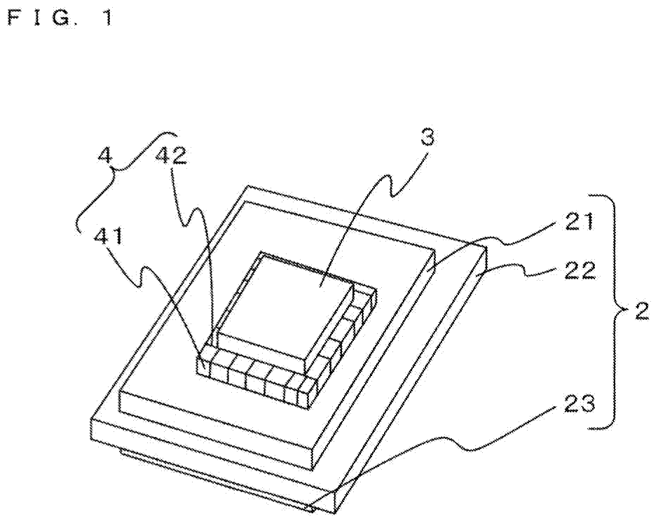

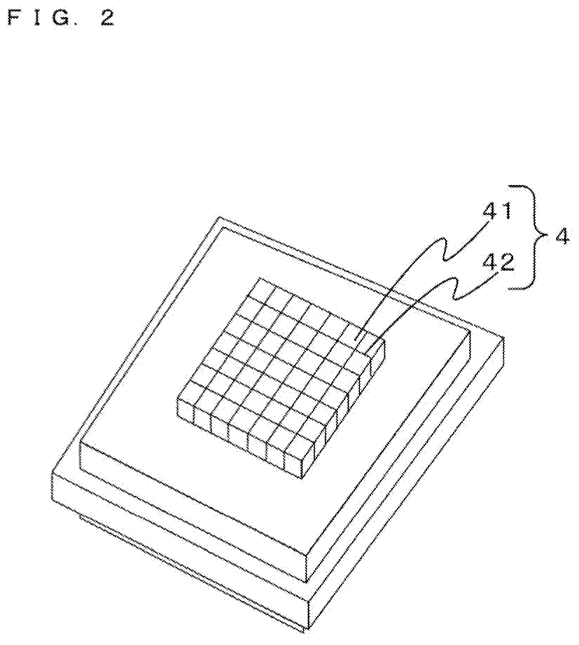

As illustrated in FIGS. 1, 2, a semiconductor device 1 according to the present invention has a structure in which a semiconductor element 3 is bonded on a surface of a circuit board 2 (conductor member) having electrodes 21, 23 formed on both sides of an insulating layer 22, with a bonding portion 4 made of a bonding material to be described later interposed therebetween. The bonding portion 4 has a mixed metal region 41 and a mixed resin region 42 as described later.

A ceramic plate of silicon nitride, alumina, aluminum nitride or the like can be used as the insulating layer 22 of the circuit board 2. From the viewpoint of heat dissipation of the entire power semiconductor device having a great heat generation amount, it is desirable to use a material having a thermal conductivity of 20 W/m·K or more, and a material having a thermal conductivity of 70 W/m·K is more desirable. Cu was used as the material of the electrodes 21, 23 provided on the front and back surfaces of the insulating layer 22. Note that the electrodes 21, 23 are not limited to be Cu, and an electrode material of Al or Ni may be used as long as a metallized layer made of one of Au, Pt, Pd, Ag, Cu, Ni, or an alloy thereof enabling preferable bonding is provided on the outermost surface.

The semiconductor element 3 is formed of a semiconductor material such as silicon (Si), silicon carbide (SiC), gallium nitride (GaN), gallium arsenide (GaAs), diamond (C), or the like. A metallized layer is provided on a surface of the semiconductor element 3 used in the semiconductor device 1 according to the first embodiment, the surface facing the circuit board 2, in order to secure the bonding property with the bonding portion 4, and the outermost surface of the metalized layer is made of one of Au, Pt, Pd, Ag, Cu, Ni, or an alloy thereof. The semiconductor element 3 using these materials is a vertical semiconductor element such as an IGBT (Insulated Gate Bipolar Transistor), a diode, or a MOSFET (metal-oxide-semiconductor field-effect transistor).

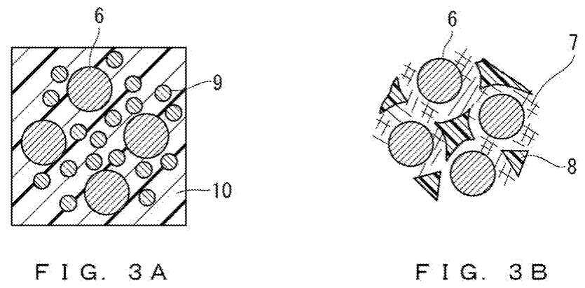

The bonding material used for the semiconductor device 1 according to the first embodiment will be described with reference to FIGS. 3A and 3B. FIG. 3A is a view illustrating a state before the bonding material used for the semiconductor device 1 according to the first embodiment is heated. The bonding material is a paste-like bonding material containing solder particles mainly made of Sn (low-melting-point metal particles 9) that melt at bonding temperature, Cu particles that do not melt at the bonding temperature (high-melting-point metal particles 6), and a polyimide resin as a filling resin 10 before being cured. The bonding material preferably contains a flux component for cleaning the metal particles 6, 9 and a surface to be bonded. In addition, it is possible to appropriately add a solvent component for adjusting characteristics such as a viscosity of a bonding material paste. Regarding the above flux component and solvent, illustration thereof is omitted from the drawing. FIG. 3B is a view illustrating a state after the bonding material 11 is heated. When the above-described bonding material is heated, the solder particles melt, wetly spread on and are brought into contact with the surfaces of the Cu particles, and thus both of them react with each other. As a result, an intermetallic compound 7 containing Cu₆SN₅ having a melting point higher than the bonding temperature is formed, and a coupled structure in which the Cu particles are bonded to each other by the intermetallic compound 7 is formed. As a result of this reaction, the solder particles are consumed, and it is possible to obtain the bonding portion 4 having a high melting point at which the bonding portion 4 does not remelt even when exposed to the bonding temperature again. In addition, the cured filling resin 8 is disposed so as to fill the interval between these metal components. As described later, in the mixed metal region 41, it is important to finely disperse the cured filling resin 8 between the Cu particles (high-melting-point metal particles 6) and the intermetallic compound 7 in order to relieve thermal stress applied to the bonding portion and to improve reliability.

The high-melting-point metal particle 6 does not necessarily have to be a spherical shape, and may be, for example, a scaly shape, a rod shape, a dendritic shape or a shape having a greatly uneven surface. It is desirable that the shape is such that adjacent high-melting-point metal particles 6 can be brought into contact with each other. Note that in a case where printability of the bonding material is considered, a spherical shape is the most desirable. It is desirable that the low-melting-point metal particles 9 are disposed so as to uniformly bond the high-melting-point metal particles 6. Therefore, it is desirable that the low-melting-point metal particle 9 has a particle diameter smaller than the particle diameter of the high-melting-point metal particle 6 and has a spherical shape. However, considering that the surface area of the low-melting-point metal particle 9 is too large and a large amount of the flux component is required if the particle diameter is made extremely small, the particle diameter of the low-melting-point metal particle 9 is preferably about 1 to 5 μm, and the particle diameter of the high-melting-point metal particle 6 is preferably about 10 to 50 μm. In a case of using solder particles as the low-melting-point metal particles 9 and Cu particles as the high-melting-point metal particles 6, the amount of the low-melting-point metal particles 9 is preferably ⅓ to ½ in mass ratio of the amount of the high-melting-point metal particles 6. As a result, the high-melting-point metal particles 6 can be bonded, and the residual of the low-melting-point metal particles 9 can be minimized.

Note that solder particles mainly made of Sn are used as the low-melting-point metal particles 9 in the first embodiment; however, any metal species that melts at temperature lower than the bonding temperature may be used. Considering that the temperature at which bonding of the semiconductor device is performed is less than 300° C., it is possible to use Sn, In, or a Sn alloy, an In alloy containing another element, or a mixture thereof. In addition, the high-melting-point metal particle 6 is not limited to the Cu particle, and may be any material that can form an intermetallic compound with the low-melting-point metal particle 9 that melts and can secure connection between the high-melting-point metal particles 6. For example, Cu, Ag, Ni, Al, Zn, Au, Pt, Pd, an alloy containing them as a main component, or a mixture thereof can be used.

As the filling resin 8, a thermosetting resin can be used, and not only a polyimide resin but also, for example, an epoxy resin, a phenol resin, a polyurethane resin, a melamine resin, a urea resin, or the like can be used. The amount of the filling resin 8 is preferably 5 to 40% by volume ratio to the entire bonding portion 4. In a case where the amount of the filling resin is smaller than this range, there is a risk that the amount of the filling resin 8 sufficient to fill the interval between the high-melting-point metal particles 6 and the intermetallic compound 7 cannot be secured. In contrast, in a case where the amount of the filling resin 8 is greater than this range, the amount of the filling resin 8 far exceeds the volume of the interval between the high-melting-point metal particles 6 and the intermetallic compound 7, and therefore the filling resin 8 may be unevenly distributed and bonding reliability may be lowered.

A method for manufacturing the semiconductor device of the first embodiment will be described with reference to the drawings.

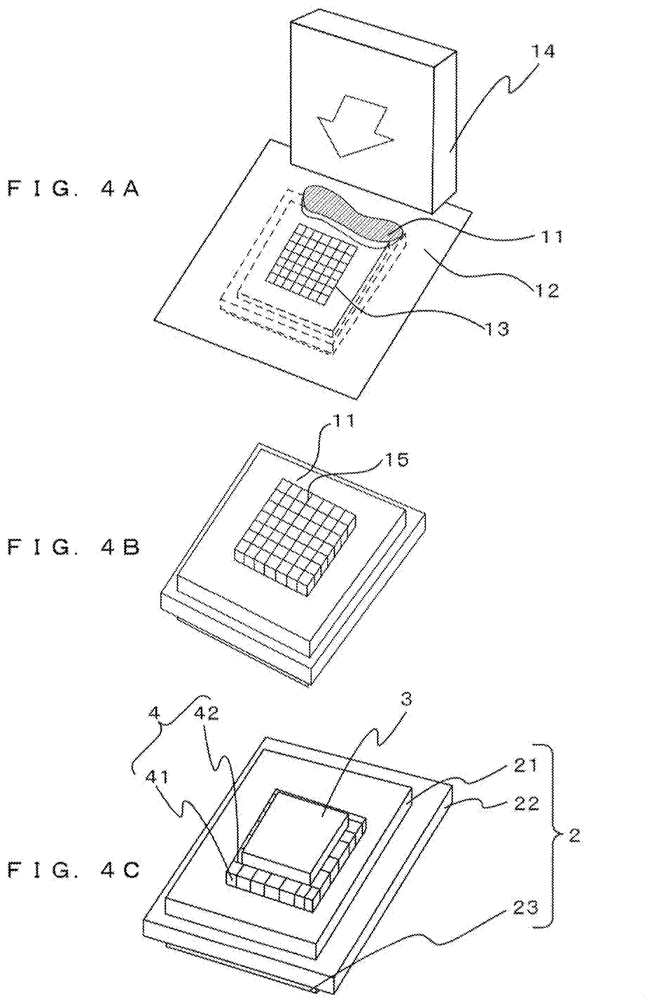

FIG. 4A to 4C show perspective views of a main part illustrating a bonding process of the conductor member and the semiconductor element in the semiconductor device according to the first embodiment. First, as illustrated in FIG. 4A, a mesh plate 12 having mesh-shaped openings 13 is disposed on an upper surface of the circuit board 2. By performing scanning so as to fill the mesh-shaped openings 13 with the bonding material 11 supplied on the above mesh plate 12 with a squeegee 14, the bonding material 11 is supplied to a region of the circuit board 2 where the semiconductor element 3 is to be bonded while the shape of the mesh-shaped openings 13 is transferred. As a result, as illustrated in FIG. 4B, the bonding material 11 is disposed on the circuit board 2 in a state of being provided with lattice-shaped gaps 15. Thereafter, the semiconductor element 3 is mounted on the supplied bonding material 11, is pressed against the bonding material 11, and is heated at the bonding temperature, thereby bonding as illustrated in FIG. 4C is achieved.

Note that the thickness of the bonding portion 4 can be appropriately selected in accordance with the required specification of the semiconductor device 1; however, can be appropriately selected from the range of 50 to 200 μm from the viewpoint of printability, economy, and reliability. In addition, the material configuring the above mesh plate 12 is selected in consideration of flexibility required upon printing and releasability from the bonding material. For example, fibers such as polyester, nylon, polyarylate, or stainless steel can be used. The diameter of the fiber is determined from a predetermined printing thickness, and in a case where the thickness of the bonding portion 4 of the semiconductor device 1 according to the first embodiment is in the range of 50 to 200 μm, it is desirable that the diameter of the fiber is 20 to 100 μm, and the pitch between the fibers is about 200 to 500 μm.

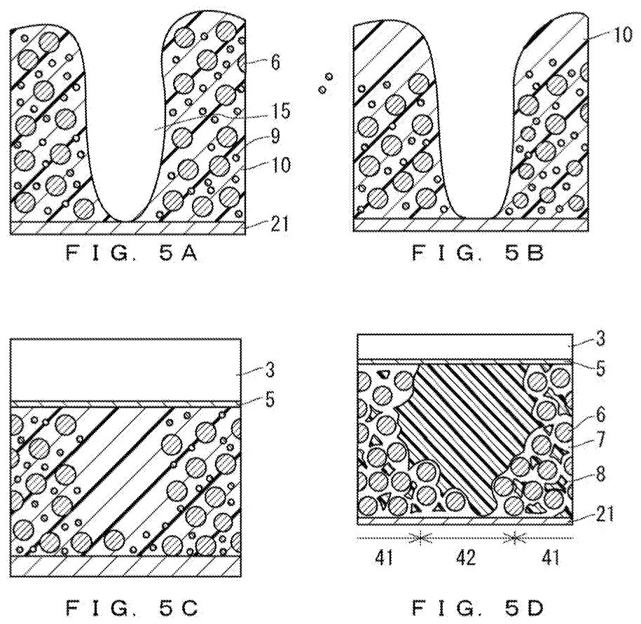

Next, the change of the bonding portion in the bonding process will be described with reference to FIGS. 5A to 5D. FIG. 5A illustrates the state immediately after printing. The gap 15 is formed in the region where the mesh was present. FIG. 5B illustrates a state when time passes after printing. The specific gravities of the high-melting-point metal particle 6 and the low-melting-point metal particle 9 are nearly 10 times greater than that of the filling resin 10 before being cured. Therefore, the high-melting-point metal particles 6 and the low-melting-point metal particles 9 settle down with the passage of time, and the filling resin 10 is unevenly distributed in the surface of the bonding material. Thereafter, by placing the semiconductor element 3 illustrated in

FIG. 5C and pressing the semiconductor element 3 against the bonding material 11, the filling resin 10 having fluidity that has been unevenly distributed in the surface of the bonding material 11 is preferentially moved to the gaps 15, and therefore, the high-melting-point metal particles 6 and the low-melting-point metal particles 9 can be reliably brought into contact with the back surface electrode 5 of the semiconductor element 3. By performing heating to the bonding temperature in this state, as illustrated in FIG. 5D, a good bonding portion 4 in which the coupled structure configured of the high-melting-point metal particles 6 and the intermetallic compound 7 is surely bonded to the semiconductor element 3 is formed. Note that in the case of the bonding material containing Cu particles, solder particles, and a polyimide resin in the first embodiment, the temperature condition upon bonding heating can be appropriately selected from about 250° C. to 300° C., which is temperature exceeding the melting point of the solder particle.

As described above, in the semiconductor device 1 according to the first embodiment, the gap 15 is provided in the bonding material, and the filling resin 10 in excess which tends to be unevenly distributed flows into the gap 15, and therefore the semiconductor device 1 in which the semiconductor element 3 and the conductor member 2 are more reliably bonded by the coupled structure configured of the high-melting-point metal particles 6 and the intermetallic compound 7 can be obtained. As a result, conduction between the semiconductor element 3 and the conductor member 2 can be sufficiently ensured, and high bonding strength can be obtained. In addition, since the void between the metal particles is filled with the cured filling resin 8, it is possible to suppress generation of a crack starting from the void.

As described above, according to the first embodiment, bonding reliability of the semiconductor device can be improved.

Note that arrangement of the gaps 15 is not limited to a lattice shape, and for example, another pattern such as a stripe shape or a dot shape is possible. In addition, not only regular arrangement but random arrangement is possible. In order to ensure uniformity of the bonding portion, it is desirable to disperse the gaps 15 over the entire surface of the supplied bonding material 11 and arrange the gaps 15 evenly at equal intervals. By supplying the bonding material 11 through the printing plate provided with the openings corresponding to arrangement of the gaps 15 to be formed, supply of the bonding material 11 and formation of the gaps 15 can be performed simultaneously.

In addition, in the first embodiment, the gaps are formed at the same time as the bonding material is supplied. However, the present invention is not limited to this, and the gaps may be formed after the bonding material is supplied. In this case, as a method of forming a gap in a supplied bonding material, for example, a method of pressing a pattern mold, scratching in a groove shape, or the like can be considered.

In addition, although the bonding material is supplied and the semiconductor element 3 is mounted on the circuit board 2, the present invention is not limited to this, and the bonding material 11 may be supplied and the circuit board 2 may be mounted on the semiconductor element 3.

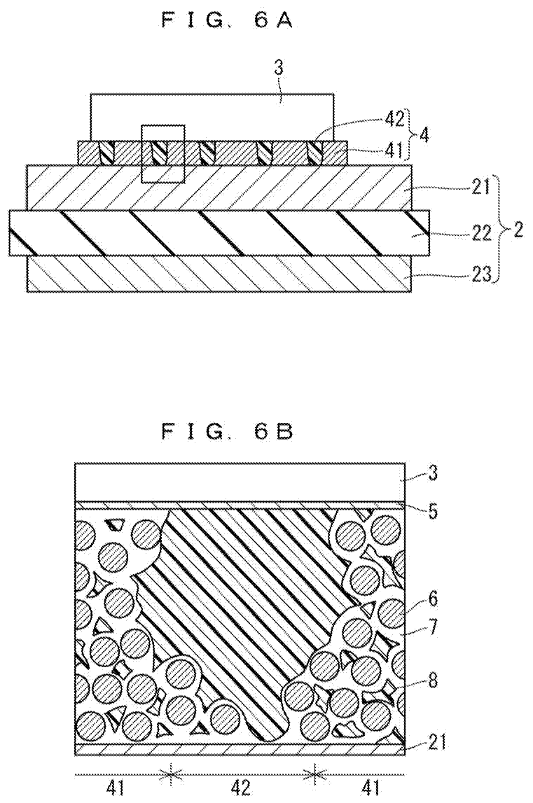

Next, the structure of the semiconductor device 1 according to the first embodiment will be described. FIG. 6A illustrates a cross-sectional view of the semiconductor device 1 manufactured by the above-described manufacturing method, cut in a cross section parallel to the bonding direction. In addition, FIG. 6B illustrates the enlarged view of the periphery of the mixed resin region 42 of the bonding portion 4 in FIG. 6A. As illustrated in FIG. 6B, the mixed metal regions 41 and the mixed resin regions 42 are present in the cross section of the bonding portion 4, and the mixed resin region 42 is located between two adjacent mixed metal regions 41. The mixed resin regions 42 are formed by flowing the filling resin 10 in the gaps 15 described above, and are arranged in a lattice shape corresponding to arrangement of the gaps 15.

In the mixed metal region 41, the coupled structure configured of the high-melting-point metal particles 6 and the intermetallic compound 7 is continuously formed from the bonding surface of the semiconductor element 3 to the bonding surface of the circuit board 2. In contrast, in the mixed resin region 42, the coupled structure is not in contact with the semiconductor element 3. Since the mixed resin region 42 is formed by flowing the filling resin 10 before being cured into the place where the gap 15 was present, the ratio of the filling resin 8 in the mixed resin region 42 is greater than that in the mixed metal region 41. Typically, the amount of the filling resin 8 in the mixed metal region 41 is less than 50% by volume, and the amount of the filling resin 8 in the mixed resin region 42 is 50% by volume or more.

Note that similarly to the gaps 15, arrangement of the mixed resin regions 42 is not limited to a lattice shape, and for example, another pattern such as a stripe shape or a dot shape is possible. In addition, not only regular arrangement but random arrangement is possible. In order to ensure uniformity of the bonding portion 4, it is desirable to disperse the mixed resin regions 42 over the entire bonding portion 4 and arrange the mixed resin regions 42 evenly at equal intervals. In addition, in the semiconductor element of the semiconductor device according to the first embodiment, an important effective circuit region contributing to conduction of electricity and heat, and an invalid circuit region such as an outer peripheral portion that does not need to obtain electrical and thermal conduction are generally provided. Therefore, it is effective to dispose the mixed resin region 42 in the ineffective region correspondingly to the circuit structure of the semiconductor element 3 and to lower rigidity of the bonding portion in order to improve bonding reliability.

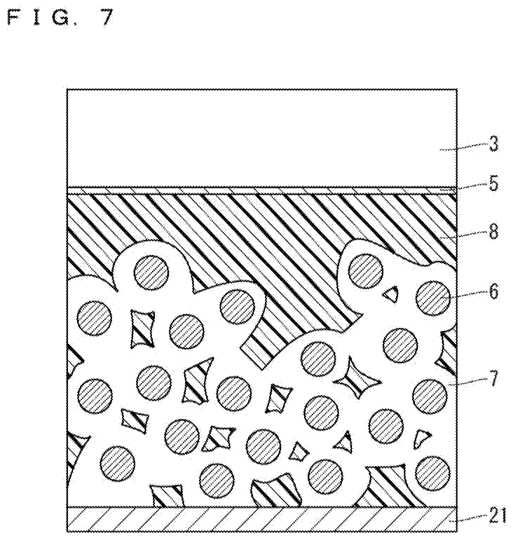

In contrast, FIG. 7 shows a cross-sectional view of a main part of a bonding portion of a conductor member and a semiconductor element in a semiconductor device according to comparative example. In the semiconductor device according to the comparative example, no gap 15 is provided in a bonding material in a bonding process. Therefore, a semiconductor element 3 is mounted in a state where filling resin 10 before being cured is unevenly distributed in a surface of the bonding material 11 due to a difference in specific gravity with metal particle in the bonding process. As a result, as illustrated in FIG. 7, filling resin 8 is unevenly distributed in the upper part of a bonding portion 4, and the semiconductor element 3 cannot be able to be sufficiently brought into contact with high-melting-point metal particles 6 and an intermetallic compound 7, conduction between the semiconductor element 3 and a circuit board 2 cannot be achieved, and the conduction performance as the semiconductor device cannot be satisfied. In addition, there is a risk that sufficient strength cannot be obtained in terms of bonding strength.

In contrast, in the semiconductor device 1 according to the first embodiment, since the filling resin 10 in excess is collected in the mixed resin region 42, and the semiconductor element 3 and the conductor member 2 are reliably bonded with electrical conduction by the coupled structure of the metal particles 6 and the intermetallic compound 7 in the mixed metal region 41, it is possible to obtain the semiconductor device having high bonding reliability both in terms of the conduction performance and in terms of bonding strength.

### Second Embodiment

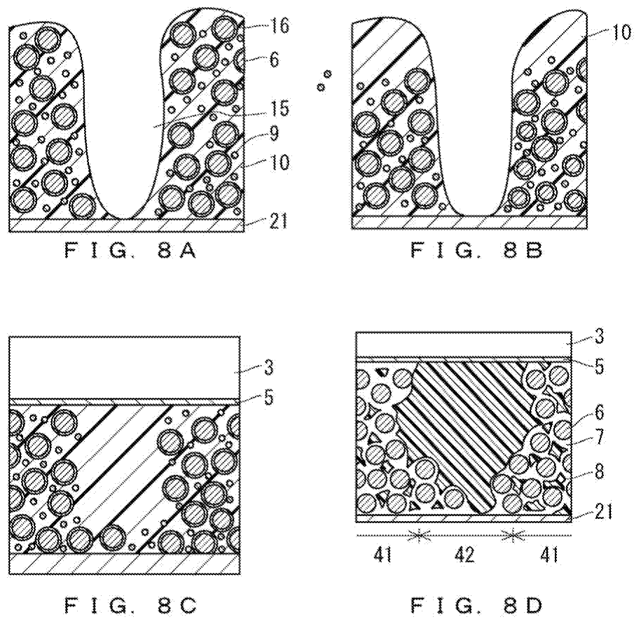

FIGS. 8A to 8D show cross-sectional views of a main part illustrating changes in a manufacturing process of a bonding portion of a conductor member and a semiconductor element in a semiconductor device according to a second embodiment of the present invention. In FIGS. 8A to 8D, low-melting-point metal particles 9, filling resin 10 before being cured, an electrode 21 of a circuit board, a gap 15, a semiconductor element 3, a back surface electrode 5, an intermetallic compound 7, a mixed metal region 41, and a mixed resin region 42 are similar to these in FIGS. 5A to 5D. The point of difference from the change in the manufacturing process of the bonding portion of the conductor member and the semiconductor element in the semiconductor device according to the first embodiment will be described below.

The second embodiment differs from the first embodiment in that a low-melting-point metal film 16 which has a composition identical to that of the low-melting-point metal particle 9 is provided on the surface of the high-melting-point metal particle 6 in the bonding material 11, and the other points are identical to the first embodiment.

By providing the low-melting-point metal film 16 on the surface of the high melting point metal particle 6, there is an effect of ensuring that the low-melting-point metal melted at bonding temperature melts wetly spreads on the surface of the high-melting-point metal particles 6. In addition, there is an effect of evenly dispersing the high-melting-point metal particles 6. Furthermore, there is an effect of reliably performing coupling of the high-melting-point metal particles 6 via the intermetallic compound 7 formed by reaction between the low-melting-point metal films 16 and the high-melting-point metal particles 6.

In a case of using solder as the low-melting-point metal particles 9 and the low-melting-point metal films 16 and Cu particles as the high-melting-point metal particles 6, the sum of the amount of the low metal films 16 and the low-melting-point metal particles 9 is preferably ⅓ to ½ in mass ratio of the amount of the high-melting-point metal particles 6. It is convenient to form the low-melting-point metal film 16 by plating. The thickness of the low-melting-point metal film 16 is suitably 1 to 5 μm which can be economically formed by plating, but can be appropriately selected within the range of the above mass ratio.

### Third Embodiment

In a third embodiment, a resin injection process is further added to the method for manufacturing the semiconductor device according to the first embodiment. The other points are identical to the first embodiment.

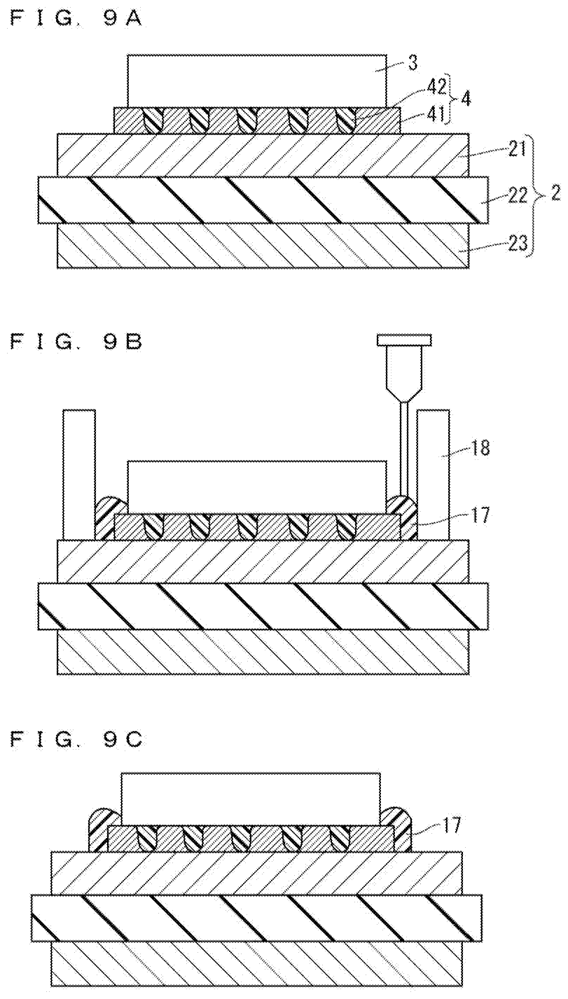

The third embodiment will be described with reference to FIGS. 9A to 9C. Similarly to the first embodiment, after bonding a semiconductor element 3 and a circuit board 2 (FIG. 9A), a resin injection process is performed.

As the resin injection process, for example, a frame 18 for resin injection is pressed against the circuit board 2 so as to surround a bonding portion 4 and is placed, and filling resin 17 is supplied to the inside of the frame 18 for resin injection (FIG. 9B). As the frame 18 for resin injection, for example, a frame made of silicone resin whose surface is coated with a fluorocarbon resin can be used. In this case, adhesion to the circuit board 2 and releasability from resin to be injected can be secured, which is preferable. At the time of supplying the filling resin 17, it is desirable to supply the filling resin 17 so as to cover the bonding portion 4. In addition, in a case where the process of connecting an electrode on a surface of the semiconductor element 3 and an external terminal is provided thereafter, it is desirable to supply the filling resin 17 in an amount not to cover the surface of the semiconductor element 3.

After the filling resin 17 is supplied, the filling resin 17 is made to permeate into the bonding portion 4 by vacuum degassing. Thereafter, the filling resin 17 is thermally cured by heating (FIG. 9C). The frame 18 for resin injection 18 may be pressed by a jig using a weight or a spring so that the frame 18 for resin injection can always be pressed onto the circuit board 2 throughout the processes from supply to thermal curing of the filling resin 17. After the filling resin 17 is cured, the frame 18 for resin injection is removed. Thus, the semiconductor device according to the present third embodiment is obtained.

By injecting the filling resin 17 after bonding, voids remaining in the bonding portion 4 at the time of the first heat curing can be surely filled. In addition, if a large amount of filling resin is added to the bonding material in an attempt to increase a void filling rate, ease of printing and ease of dispersion of the bonding material may be impaired. However, if the filling resin is injected after the bonding process, there is no need to increase the amount of resin in the bonding material at the time of printing. As a result, the void filling rate can be increased without losing the ease of printing and the ease of dispersion.

Note that means for injecting resin is not limited to this, and any means capable of injecting resin into the voids remaining in the bonding portion 4 may be used.

### Fourth Embodiment

The present embodiment is an application of the semiconductor device according to the above-described first to third embodiments to a power conversion apparatus. Although the present invention is not limited to a specific power conversion apparatus, a case where the present invention is applied to a three-phase inverter will be described below as a fourth embodiment.

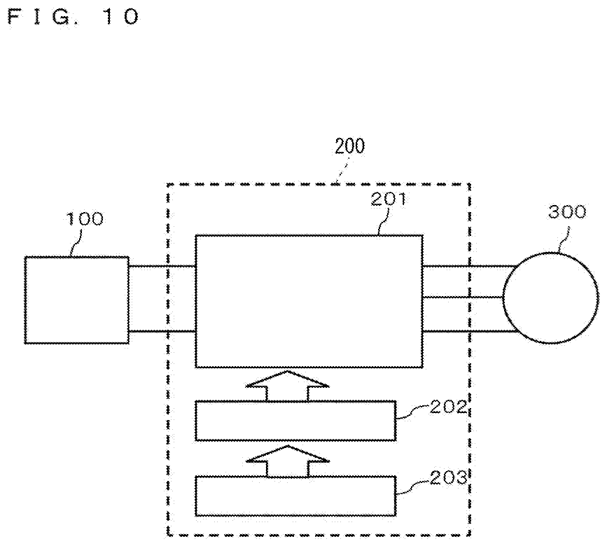

FIG. 10 is a block diagram illustrating a configuration of a power conversion system to which the power conversion apparatus according to the present embodiment is applied.

The power conversion system illustrated in FIG. 10 is configured of a power supply 100, a power conversion apparatus 200, and a load 300. The power supply 100 is a DC power supply, and supplies DC power to the power conversion apparatus 200. The power supply 100 can be configured of various things, for example, can be configured of a DC system, a solar cell, or a storage battery, or may be configured of a rectifier circuit connected to an AC system or an AC/DC converter. In addition, the power supply 100 may be configured of a DC/DC converter that converts DC power output from a DC system into predetermined power.

The power conversion apparatus 200 is a three-phase inverter connected between the power supply 100 and the load 300, converts DC power supplied from the power supply 100 into AC power, and supplies the load 300 with AC power. As illustrated in FIG. 10, the power conversion apparatus 200 includes a main conversion circuit 201 which converts DC power into AC power and outputs the AC power, and a control circuit 203 which outputs a control signal that controls the main conversion circuit 201 to the main conversion circuit 201.

The load 300 is a three-phase motor driven by AC power supplied from the power conversion apparatus 200. Note that the load 300 is not limited to a specific application, and is a motor mounted on various electric apparatuses, and is used as, for example, a motor for a hybrid car, an electric car, a rail car, an elevator, or an air conditioner.

Hereinafter, details of the power conversion apparatus 200 will be described. The main conversion circuit 201 includes a switching element and a freewheel diode (not illustrated), and the switching element performs switching to convert DC power supplied from the power supply 100 into AC power and supplies the AC power to the load 300. Although there are various specific circuit configurations of the main conversion circuit 201, the main conversion circuit 201 according to the present embodiment is a two-level three-phase full bridge circuit, and can be configured of six switching elements and six freewheel diodes connected in reverse parallel to the switching elements, respectively. Each switching element and each freewheel diode of the main conversion circuit 201 are configured of a semiconductor module 202 using the semiconductor device 1 corresponding to any one of the first to third embodiments described above. Every two switching elements among the six switching elements are connected in series to constitute upper and lower arms, and the upper and lower arms constitute phases (U phase, V phase, W phase) of a full bridge circuit, respectively. Output terminals of the upper and lower arms, that is, three output terminals of the main conversion circuit 201, are connected to the load 300.

In addition, although the main conversion circuit 201 includes a drive circuit (not illustrated) for driving each switching element, the drive circuit may be built in the semiconductor module 202, or a configuration where a drive circuit is provided separately from the semiconductor module 202 is possible. The drive circuit generates a drive signal for driving the switching element of the main conversion circuit 201, and supplies the drive signal to a control electrode of the switching element of the main conversion circuit 201. Specifically, in accordance with a control signal from a control circuit 203 described later, a drive signal for turning on the switching element and a drive signal for turning off the switching element are output to the control electrode of each switching element. In a case where the switching element is maintained in the on state, the drive signal is a voltage signal (on signal) equal to or higher than a threshold voltage of the switching element, and in a case where the switching element is maintained in an off state, the drive signal is a voltage signal (off signal) equal to or lower than the threshold voltage of the switching element.

The control circuit 203 controls the switching elements of the main conversion circuit 201 so that desired power is supplied to the load 300. Specifically, the time (on time) in which each switching element of the main conversion circuit 201 should be turned on is calculated according to power to be supplied to the load 300. For example, the main conversion circuit 201 can be controlled by PWM control of modulating the on time of the switching element according to the voltage to be output. Then, a control command (control signal) is output to the drive circuit included in the main conversion circuit 201 so that the on signal is output to the switching element to be turned on and the off signal is output to the switching element to be turned off at each time point. The drive circuit outputs an on signal or an off signal as a drive signal to the control electrode of each switching element according to this control signal.

In the power conversion apparatus according to the present embodiment, since the semiconductor modules using the semiconductor devices according to the first to third embodiments are applied as the switching elements and the freewheel diodes of the main conversion circuit 201, reliability can be improved.

In the present embodiment, an example in which the present invention is applied to the two-level three-phase inverter has been described; however the present invention is not limited to this, and can be applied to various power conversion apparatuses. In the present embodiment, the two-level power conversion apparatus is used; however, a three-level or multi-level power conversion apparatus may be used, and in a case of supplying power to a single-phase load, the present invention may be applied to a single-phase inverter. In addition, in a case of supplying power to a DC load or the like, the present invention can be applied to a DC/DC converter or an AC/DC converter.

In addition, the power conversion apparatus to which the present invention is applied is not limited to the case where the load described above is a motor, and, for example, may be used as a power supply apparatus of an electric discharge machine, a laser machine, an induction heating cooker, or a noncontact machine power supply system, and can also be used as a power conditioner of a solar power generation system, a storage system, or the like.

### EXPLANATION OF REFERENCE SIGNS

1: Semiconductor device

2: Circuit board

3: Semiconductor element

4: Bonding portion

5: Back surface electrode

6: High-melting-point metal particle

7: Intermetallic compound

8: Filling resin

9: Low-melting-point metal particle

10: Filling resin before being cured

11: Bonding material

12: Mesh plate

13: Opening

14: Squeegee

15: Gap

16: Low-melting-point metal film

17: Injected filling resin

18: Frame for resin injection

21, 23: Electrode of circuit board

22: Insulating substrate of circuit board

41: Mixed metal region

42: Mixed resin region

100: Power supply

200: Power conversion apparatus

201: Main conversion circuit

202: Semiconductor module

203: Control circuit

300: Load

1. A semiconductor device comprising:
a semiconductor element;
a conductor member; and
a bonding portion that bonds the semiconductor element and the conductor member with electrical conduction;
the bonding portion containing first particles that contain a first metal, an intermetallic compound that contains the first metal and a second metal having a melting point lower than a melting point of the first metal and couples the first particles to each other, and a filling resin,
the bonding portion having, in a cross section parallel to a bonding direction,
mixed metal regions in which a coupled structure including the first particles and the intermetallic compound is continuously formed from a bonding surface with the semiconductor element to a bonding surface with the conductor member, and
a mixed resin region formed between two of the mixed metal regions that are adjacent to each other, in which a ratio of the filling resin is greater than a ratio of the filling resin in the mixed metal region, and the coupled structure is not in contact with at least one of the semiconductor element or the conductor member.

2. The semiconductor device according to claim 1, wherein the ratio of the filling resin in the mixed resin region is 50% by volume or more.

3. The semiconductor device according to claim 1, wherein the mixed resin regions are disposed to be dispersed over entirety of the bonding portion.

4. The semiconductor device according to claim 1, wherein the mixed resin regions are disposed at equal intervals.

5. The semiconductor device according to claim 1, wherein the mixed resin regions are disposed in a lattice shape.

6. The semiconductor device according to claim 1, wherein
the first metal contains any one or more of Cu, Ag and Ni, and
the second metal contains any one or more of Sn and In.

7. The semiconductor device according to claim 6, wherein
the first metal contains Cu,
the second metal contains Sn, and
the intermetallic compound includes Cu₆Sn₅.

8. The semiconductor device according to claim 1, wherein a ratio of the filling resin in the bonding portion is not less than 5% by volume and not more than 40% by volume.

9. A power conversion apparatus comprising:
a main conversion circuit that has the semiconductor device according to claim 1, and converts input power and outputs the power;
a drive circuit that outputs a drive signal for driving the semiconductor device to the semiconductor device; and
a control circuit that outputs a control signal for controlling the drive circuit to the drive circuit.

10. A method for manufacturing a semiconductor device comprising:
a bonding material supply process of supplying a bonding material that contains first particles containing a first metal, second particles containing a second metal having a melting point lower than a melting point of the first metal, and a filling resin on one of a semiconductor element or a conductor member, and forming a gap in a surface of the bonding material;
a mounting process of mounting and pressing another of the conductor member or the semiconductor element on and against the bonding material in which the gap is formed, and moving the filling resin unevenly distributed in the surface of the bonding material to the gap; and
a bonding process of heating the bonding material at temperature higher than the melting point of the second metal and lower than the melting point of the first metal.

11. The method for manufacturing the semiconductor device according to claim 10, wherein in the bonding material supply process, the gaps are formed to be dispersed over entirety of the surface of the bonding material.

12. The method for manufacturing the semiconductor device according to claim 10, wherein in the bonding material supply process, the gaps are formed at equal intervals.

13. The method for manufacturing the semiconductor device according to claim 10, wherein in the bonding material supply process, the gaps are formed in a lattice shape.

14. The method for manufacturing the semiconductor device according to claim 10, wherein in the bonding material supply process, supply of the bonding material and formation of the gap are simultaneously performed by supplying the bonding material through a printing plate provided with an opening corresponding to arrangement of the gap to be formed.

15. The method for manufacturing the semiconductor device according to claim 10, wherein in the bonding material supply process, the gap is formed after the bonding material is supplied.

16. The method for manufacturing the semiconductor device according to claim 10, wherein in the bonding material supply process, a film containing the second metal is provided on a surface of the first particle.

17. The method for manufacturing the semiconductor device according to claim 10 further comprising a resin injection process of injecting the filling resin into a bonding portion made of the bonding material after the bonding process.
